(19) United States
(12) Patent Application Publication
(10) Pub. No.: US 2009/0238996 A1
(43) Pub. Date: Sep. 24, 2009

(54) Substrate For Growth of Carbon Nanotube, Method for Growth of Carbon Nanotube, Method for Control of Particle Diameter of Catalyst for Growth of Carbon Nanotube and Method for Control of Carbon Nanotube Diameter

(75) Inventors: Haruhisa Nakano, Ibaraki (JP); Takahisa Yamazaki, Ibaraki (JP); Hirohiko Murakami, Ibaraki (JP)

Correspondence Address: ARENT FOX LLP, 1050 CONNECTICUT AVENUE, N.W., SUITE 400, WASHINGTON, DC, 20036, US

(73) Assignee: ULVAC, Inc., Chigasaki-shi, Kanagawa (JP)

(21) Appl. No.: 12/302,599

(22) PCT Filed: May 29, 2007
(86) PCT No.: PCT/JP2007/060859

§ 371 Date: Nov. 26, 2008

(30) Foreign Application Priority Data
May 29, 2006 (JP) 2006-147725
Sep. 5, 2006 (JP) 2006-239748

(51) Int. Cl. H05H 1/24; C23C 16/50; B32B 15/04

(52) U.S. Cl. 427/569; 428/457; 428/553; 977/843

(57) ABSTRACT

A substrate for the growth of a carbon nanotube having a catalyst layer microparticulated by using an arc plasma gun. CNT is grown on the catalyst layer by thermal CVD or remote plasma CVD. The particle diameter of the catalyst for the growth of CNT is regulated by the number of shots of the are plasma gun. CNT is grown on the catalyst layer having a regulated catalyst particle diameter by thermal CVD or remote plasma CVD to regulate the inner diameter or outer diameter of CNT.

### TECHNICAL FIELD

The present invention relates to a substrate for use in the growth of a carbon Nanotube (hereunder referred to as “CNT”), a method for the growth of CNT, a method for controlling the particle size of a catalyst used for the growth of CNT, and a method for the control of the diameter of CNT.

### BACKGROUND ART

In the case of the substrate conventionally used for the growth of CNT, it is in general prepared by the deposition of a catalyst on a starting substrate in the form of a thin film, according to, for instance, the sputtering technique or the EB vapor deposition technique, and the subsequent conversion of the catalyst thus spread on the surface of the thin film formed on the substrate into fine particles (or microparticles) or the subsequent microparticulation of the catalyst by such a process as heating prior to or during the CNT-growth, and the substrate provided thereon with the resulting microparticulated catalyst is thus used as such a substrate for the growth of CNT. In this case, the particle size of the catalyst particles is influenced by a variety of factors such as the kind of an underlying buffer layer, the process conditions and the thickness of a catalyst film formed and therefore, the control thereof would be quite difficult. In addition, the particle size of the resulting catalyst microparticles is liable to be large since the catalyst is micronized or microparticulated through the aggregation thereof. It has been said that the smaller the diameter of the catalyst microparticles, the easier the growth of CNT, but the particle size thereof cannot easily be controlled because of the variation thereof depending on, for instance, the thickness of the catalyst film formed, the process conditions for pre-treatments and the reaction conditions, as has been described above.

Contrary to this, there is also known such a method which comprises the steps of preliminarily preparing catalyst particles instead of the micronization or microparticulation of a catalyst and then fixing the catalyst microparticles onto the substrate surface, but this method requires the use of such a superfluous step that simply microparticles are prepared in advance.

Alternatively, there has also been known a method comprising dispersing or dissolving a catalyst prepared in the form of microparticles in a solvent and then applying the resulting dispersion or solution onto the surface of a substrate, but this method suffers from such problems that it requires the use of a separate process for preparing microparticles of a catalyst and that the microparticles thus prepared and applied onto the substrate may undergo cohesion.

Furthermore, there has also been known a method in which a CNT layer or film is directly grown on a substrate consisting of Ni, Fe, Co or an alloy of at least two members selected from these metals (see, for instance, Patent Document 1 specified below). In this case, the usual plasma CVD technique or the like is used, and therefore this technique is limited in the CNT growth at a low temperature. Although the growth temperature may vary depending on the applications of the resulting CNT film, the CNT growth process should sometimes be carried out at a low temperature. This is because, if using the plasma CVD technique, the growth temperature would be increased due to the energy of the plasma.

To solve the drawbacks of the foregoing usual plasma CVD technique, there has been proposed a method in which the CNT growth is carried out using the remote plasma CVD technique in order to prevent any increase of the substrate temperature due to the energy of plasma (see, for instance, Patent Document 2 specified below). In the growth of CNT, this method comprises the steps of generating a plasma such that a substrate is not directly brought into contact with the plasma; heating the substrate using a heating means; and supplying the substrate surface with a raw gas decomposed in the plasma to thus grow CNT on the substrate surface. In this method, however, a catalyst is not micronized and accordingly, any satisfactory CNT growth is not always ensured.

Patent Document 11 Japanese Un-Examined Patent Publication 2001-48512 (the contents of Claims);

Patent Document 2. Japanese Un-Examined Patent Publication 2005-350342 (the contents of Claims).

### DISCLOSURE OF THE INVENTION

### Problems that the Invention is to Solve

As has been discussed above, the aforementioned conventional CNT-growing methods suffer from such problems that CNT cannot be grown in a high efficiency and at a temperature as low as possible so as to be used in a variety of fields including the semiconductor element-fabrication field and that these methods cannot control the particle size of a catalyst for the growth of CNT and the inner diameter and/or outer diameter of CNT. Accordingly, there has been desired for the development of a technique which can easily produce desired catalyst microparticles, for instance, catalyst microparticles having a controlled particle size, when forming a catalyst layer, and which permits the effective growth of desired CNT, for instance, CNT having a controlled diameter on the catalyst layer.

Accordingly, it is an object of the present invention to solve the problems associated with the conventional techniques and more particularly to provide a substrate for the effective growth of CNT, a method for the efficient growth of desired CNT on the surface of the substrate, a method for controlling the particle size of a catalyst used for CNT-growth, and a method for controlling the diameter of the resulting CNT when growing CNT on the catalyst whose particle size has been controlled.

### Means for the Solution of the Problems

The substrate for the growth of a carbon nanotube (CNT(s)) according to the present invention is characterized in that it has, on its surface, a catalyst layer formed using a coaxial type vacuum arc deposition apparatus (hereunder referred to as “arc plasma gun”).

The catalyst layer on the substrate surface preferably consists of catalyst microparticles whose particle size has been regulated by controlling the number of shots of the arc plasma gun or has been dependent on the number of shots.

The substrate for the CNT-growth according to the present invention is likewise preferably provided with a buffer layer as an underlying layer for a catalyst layer and the catalyst layer formed on the buffer layer using such an arc plasma gun. It is also preferred, in this case, that the catalyst layer formed on the buffer layer consists of catalyst particles whose particle size has been regulated by controlling the number of shots of the arc plasma gun.

The foregoing buffer layer is preferably constituted by a film of a metal selected from the group consisting of Ti, Ta, Sn, Mo and Al; a film of a nitride of such a metal; or a film of an oxide of such a metal. The aforementioned metals, nitrides and oxides may be used as a mixture of at least two thereof, respectively.

The foregoing catalyst layer is preferably one formed using a target for the arc plasma gun which is composed of either one of Fe, Co and Ni; or an alloy or a compound containing at least one of these metals; or a mixture of at least two members selected from the group consisting of these metals, the alloys and the compounds.

It is further preferred that the foregoing catalyst layer is one the catalyst layer itself obtained by forming such a basic catalyst layer, then activating the same with hydrogen radicals and optionally applying a catalyst-protecting layer which consists of a metal or a nitride onto the activated catalyst layer. The metal used for forming the catalyst-protecting layer is preferably a member selected from Ti, Ta, Sn, Mo and Al and the nitride is preferably that of such a metal. The foregoing metals and nitrides may be a mixture of at least two of them, respectively.

The use of the substrate having the foregoing construction would permit the CNT-growth even at a low temperature on the order of not more than 700° C., preferably not more than 400° C., more preferably not more than 350° C. and further preferably not more than 300° C.

The method for the CNT-growth according to the present invention is characterized in that a catalyst layer is formed on the surface of a substrate using an arc plasma gun and then CNT is grown on the catalyst layer according to the thermal CVD technique or the remote plasma CVD technique. The method of the present invention thus certainly permits the micronization of a catalyst and likewise the growth of desired CNTs at a lower temperature.

In the foregoing method for the CNT-growth, it is preferred to use a substrate provided with a buffer layer as an underlying layer for the catalyst layer and the buffer layer is preferably constituted by a film of a metal selected from the group consisting of Ti, Ta, Sn, Mo and Al, a film of a nitride of such a metal, or a film of an oxide of such a metal. The aforementioned metal film, nitride film or oxide film may be a film of a mixture of at least two thereof, respectively.

In the foregoing method for the CNT-growth, it is preferred to use a target for the arc plasma gun which is composed of either one of Fe, Co and Ni; or an alloy or a compound containing at least one of these metals; or a mixture of at least two members selected from the group consisting of these metals, the alloys and the compounds. In addition, after the formation of the foregoing catalyst layer, the catalyst layer is preferably activated with hydrogen radicals and CNT is subsequently grown on the catalyst layer thus activated. Moreover, after the formation of the catalyst layer, a catalyst-protecting layer consisting of a metal or a nitride is preferably formed on the surface of the catalyst layer. The purpose of forming the protective layer is to prevent any possible deactivation of the catalyst layer observed when the layer is exposed to the atmosphere such as the atmospheric air and to prevent the formation of any amorphous carbon film on the catalyst layer during the CNT-growth. The metal used for forming the catalyst-protecting layer is a member selected from Ti, Ta, Sn, Mo and Al and the nitride is that of such a metal. The foregoing metals and nitrides may be a mixture of at least two of them, respectively.

The method for controlling the particle size of the catalyst particles constituting a layer thereof according to the present invention is characterized in that the particle size thereof is controlled by changing the number of shots of this arc plasma gun when forming the catalyst layer on the substrate surface. Thus, the method of the present invention permits the appropriate selection of the particle size of the catalyst particles in proportion to the desired diameter of CNT to be grown on the catalyst layer.

In the foregoing method for controlling the particle size of the catalyst particles, it is preferred to use a substrate provided with a buffer layer as an underlying layer for the catalyst layer and the buffer layer is preferably constituted by a film of a metal selected from the group consisting of Ti, Ta, Sn, Mo and Al, a film of a nitride of such a metal, or a film of an oxide of such a metal and it is likewise preferred to use a target for the arc plasma gun which is composed of either one of Fe, Co and Ni; or an alloy or a compound containing at least one of these metals; or a mixture of at least two members selected from the group consisting of these metals, the alloys and the compounds.

The method for controlling the diameter of CNT according to the present invention is characterized in that a catalyst layer consisting of catalyst particles having a particle size controlled according to the aforementioned catalyst particle size-controlling method is formed on the surface of a substrate using an arc plasma gun, CNT is then grown on the catalyst layer according to the thermal CVD technique or the remote plasma CVD technique to thus control the diameter or the inner and/or outer diameters of the growing CNT. Thus, the method of the present invention permits the appropriate growth of CNT in proportion to the desired diameter thereof.

In the foregoing CNT diameter-controlling method, it is preferred that, after the formation of the foregoing catalyst layer, the catalyst layer is activated with hydrogen radicals and subsequently CNTs are grown on the catalyst layer thus activated. Moreover, after the formation of the catalyst layer, a catalyst-protecting layer consisting of a metal or a nitride is preferably formed on the surface of the catalyst layer. Preferably, the metal used for forming the catalyst-protecting layer is a member selected from Ti, Ta, Sn, Mo and Al and the nitride used in the formation of the same is that of such a metal.

### EFFECTS OF THE INVENTION

According to the present invention, CNT is grown according to the thermal CVD technique or the remote plasma CVD technique, while using, as a substrate, one provided thereon with a micronized catalyst formed using an arc plasma gun and accordingly, the present invention permits the achievement of such an effect that CNT can efficiently be grown at a desired temperature and that CNT can, for instance, be grown as a wiring material or electrical connection material or the like in the semiconductor device-fabricating process.

Moreover, the present invention likewise permits the achievement of such an effect that a catalyst film can be formed from catalyst microparticles whose particle size has been controlled in advance since the method of the present invention comprises the use of the arc plasma gun and this in turn permits the control of the inner and/or outer diameters of the grown CNT.

Furthermore, according to the method of the present invention, catalyst microparticles are incident upon or supplied to the surface of a substrate at high energy conditions through the use of an arc plasma gun to thus be formed into a catalyst film and therefore, the catalyst microparticles constituting the catalyst film never undergoes any cohesion even when the temperature thereof is raised.

### BEST MODE FOR CARRYING OUT THE INVENTION

According to the CNT-growing method of the present invention, a catalyst layer can be formed on the surface of a substrate using an arc plasma gun while micronizing the catalyst and simultaneously, CNT can efficiently be grown over a desired wide CNT-growing temperature range and preferably at a low CNT-growing temperature by the use of the radical species of a raw gas for CNT-growth as a starting material and the impartment of a high energy to the starting atoms (molecules) according to the thermal CVD technique or the remote plasma CVD technique in this respect, if the catalyst layer is subjected to a hydrogen radical-treatment to thus activate the catalyst and if a protective layer is formed on the surface of the catalyst layer, prior to the CNT-growth, the CNT-growing temperature can further be reduced to a low level and CNT can further efficiently be grown.

As has been discussed above, the present invention permits the reduction of the CNT-growing temperature (to a level of not more than 400° C., preferably not more than 350° C. and more preferably not more than 300° C.), through the combinatorial use of the formation of a micronized catalyst layer on the surface of a substrate by the use of an arc plasma gun and the thermal CVD technique or the remote plasma CVD technique.

The formation of a micronized catalyst layer by the use of an arc plasma gun can be carried out using any known arc plasma gun and it may, for instance, be carried out using a coaxial arc plasma gun as shown in FIG. 1. The arc plasma gun as shown in FIG. 1 comprises a cylindrical anode 11 wherein one end thereof is closed, while the other end thereof is opened, a cathode 12 and a trigger electrode 13 (such as a ring-like trigger electrode). The cathode 12 is concentrically positioned within the anode 11 and separated from the wall of the anode at a constant distance. To the tip of the cathode 12 (corresponding to the end thereof on the side of the open end of the anode 11), there are attached a catalyst material 14 serving as a target for the arc plasma gun and the trigger electrode 13, in which these two members are adjacent to one another through an insulator 15. This cathode 12 may likewise entirely be constituted from the catalyst material. The insulator 15 is attached thereto so as to insulate the cathode 12 and the trigger electrode 13 is fitted on the cathode through a dielectric material 16. These anode 11, cathode 12 and trigger electrode 13 are maintained in their electrically insulated states due to the presence of the insulator 15 and the dielectric material 16. The insulator 15 and the dielectric material 16 may be united or may constitute separate components.

The cathode 12 and the trigger electrode 13 are connected to one another through a trigger power source 17 consisting of a pulse transformer and the cathode 12 and the anode 11 are connected through an arc power source 18. The arc power source 18 consists of a DC voltage source 19 and a condenser unit 20, the both ends of the condenser unit are connected to the anode 11 and the cathode 12, respectively and the condenser unit 20 and the DC voltage source 19 are connected in parallel. In this connection, however, the condenser unit 20 is charged by the action of the DC voltage source 19 at any time.

When forming catalyst microparticles on the surface of a substrate using the foregoing arc plasma gun, a pulse voltage is applied to the trigger electrode 13 through the trigger power source 17 to thus generate a trigger discharge (creeping discharge) between the catalyst material 14 and the trigger electrode 13 fitted on the cathode 12. This trigger discharge can induce an arc discharge between the catalyst material 14 and the anode 11 and the discharge is interrupted through the emission of the charges accumulated in the condenser unit 20. The catalyst material is melted during the arc discharge to thus form microparticles (ions and electrons in a plasma state) thereof. These microparticles consisting of such ions and electrons are emitted or discharged into a vacuum chamber shown in FIG. 2 as will be described later through the opening of the anode (discharge port) A and they are then fed onto a substrate to be processed, which is placed in the vacuum chamber, to thus form a layer of the catalyst microparticles. In this respect, it is preferred that this trigger discharge operation is repeated over a plurality of times to thus induce an arc discharge for each corresponding trigger discharge.

In the present invention, it is preferred that the wiring length or electrical connection length of the condenser unit 20 is limited to not more than 50 mm, the capacity of the condenser unit 20 connected to the cathode 12 is set at a level ranging from 2200 to 8800 μF and the discharge voltage is set at a level of 50 to 800 V, so that the peak electric current of the foregoing arc discharge is equal to a level of not less than 1800 A and so that the arc current generated due to each arc discharge can be extinguished within a short period of time on the order of not longer than 300 μsec. In addition, the trigger discharge is preferably generated at a frequency of about 1 to 10 times/sec. Further it is likewise preferred that a vacuum chamber shown in FIG. 2 as will be detailed later is evacuated to a vacuum, an inert gas such as helium gas is introduced into the chamber to a pressure lower than the atmospheric pressure and the foregoing ions or the like are emitted or discharged into the gas atmosphere to thus form microparticles of the catalyst on the substrate. In this respect, the arc current is induced once per trigger discharge and the arc current-flowing time is set at a level of not longer than 300 μsec, but a Certain time is required for charging the condenser unit 20 provided in a circuit for the arc power source 18. Accordingly, the period of generating a trigger discharge is so established that it falls within the range of from 1 to 10 Hz and the condenser is charged in such a manner that the arc discharge is generated at such a period.

When forming catalyst microparticles on the substrate surface using the arc plasma gun, the particle size of the catalyst microparticles can be controlled by adjusting the number of shots of the arc plasma gun. For this reason, CNT can be grown while appropriately controlling the inner and/or outer diameters of the grown CNT by the control of the catalyst particle size through the change of the number of shots so as to be in accord with the intended diameter of CNT to be grown.

In this case, the cathode (target) of the arc plasma gun is preferably formed from at least one of Fe, Co and Mi, an alloy or a compound comprising at least one such metal, or a mixture containing at least two of them, as the catalyst material. Only the tip (serving as a target) of the cathode may be formed from these materials.

When controlling the catalyst particle size through the adjustment of the shot number of the plasma gum, the particle size is preferably not less than 1 Å and not more than 5 nm as expressed in terms of the film thickness although it may vary depending on the film-forming conditions used. If it is less than 1 Å, the space or distance between the neighboring particles which are discharged or emitted from the arc plasma gun and arrive at the substrate surface is too large and the catalyst particle size is hardly reflect the number of shots of the gun, while if it is thicker than 5 nm, the catalyst particles are accumulated to give a layer and in this case, the catalyst particle size is likewise hardly reflect the number of shots thereof and the control of the particle size cannot be expected. This accordingly makes it quite difficult to control the diameter of the grown CNT.

The correlation between the foregoing particle size and the number of shots may vary depending on the predetermined conditions for the arc plasma gun, but when forming the foregoing catalyst layer using the arc plasma gun available from ULVAC INC., the particle size on the order of 1 Å as expressed in terms of the film thickness corresponds to, for instance, that accomplished by 10 shots under the following conditions: the voltage of 60 V; the capacity of the condenser unit of 8800 μF; the substrate-to-target distance of 80 mm; and the thickness per shot of 0.1 Å, while that of 5 nm as expressed in terms of the film thickness corresponds to that accomplished by 500 shots. In this case, if the voltage is adjusted to about 80 V and about 100 V, the particle sizes per one shot as expressed in terms of the film thickness correspond to 0.5 Å and 1 Å, respectively.

As has been described above, the catalyst particle size can be controlled depending on the number of shots, on the basis of the established (or predetermined) film thickness per one shot while taxing into consideration the film-forming conditions for the arc plasma gun. For instance, if the film thickness per one shot is set at 0.1 Å/shot, a catalyst layer having a desired thickness can be formed by 10 to 500 shots and if it is set at 0.5 Å/shot, a catalyst layer having such a desired thickness can be formed by 2 to 100 shots. Thus, the catalyst particle size can be controlled in proportion to the shot number of the arc plasma gun. As the shot number thereof increases, neighboring particles among those arriving at the substrate undergo cohesion to thus form particles having a large particle size and therefore, the catalyst particle size should be controlled by the appropriate selection of any desired shot number while taking account of the interrelation between the catalyst particle size and the diameter of CNT to be grown on the catalyst microparticles.

In this connection, however, if the film thickness per one shot exceeds 0.5 Å and reaches about 1 Å, a large number of catalyst particles are scattered in the processing chamber at a time and this would make the control of the particle size thereof quite difficult. For this reason, the film thickness per one shot of the gun, as a film-forming condition, is preferably not more than about 0.5 Å.

As has been discussed above, the control of the catalyst particle size (film thickness) would permit the control of the diameter of CNT to be grown on the catalyst layer. For instance, when CNT is grown, according to a known method, on catalyst layers each having a film thickness of 5 Å or 10 Å and formed according to the foregoing method, the inner diameter distribution observed for the CNT thus grown may vary depending on the film thickness and the inner diameter is almost identical to the catalyst particle size. The foregoing thus clearly indicates that the diameter of a catalyst and that of the grown CNT can be controlled by adjusting the shot number of the arc plasma gun. Accordingly, the present invention permits the formation of CNT having any desired diameter.

For instance, if CNT is applied to a device such as a semiconductor device, in particular, a plurality of CNTs are used in a bundle, the characteristic properties of CNT are greatly influenced by the CNT diameter and the CNT density related thereto. Accordingly, it would be quite important that the inner and/or outer diameters of CNT can arbitrarily be controlled.

Moreover, preferably used herein as the CNT-growing methods are the thermal CVD technique and the remote plasma CVD technique as has been discussed above. The usual methods such as the plasma CVD method are not preferred since the catalyst layer is etched by the usual methods.

The correlation between the catalyst particle size and the inner and/or outer diameters of the grown CNT may depend on the CNT-growing method used and the conditions thereof, but a method which can reduce the shot number of the arc plasma gun is rather preferred to produce CNTs having a small diameter. In addition, when controlling the catalyst particle size, the CNT-growing temperature is preferably one already described above, for instance, not higher than 700° C. This is because if CNT is grown at a temperature higher than the same, a problem arises such that the catalyst microparticles constituting the catalyst layer formed using the arc plasma gun undergoes cohesion to thus increase the catalyst particle size.

FIG. 2 shows an embodiment of a catalyst microparticle-production apparatus which makes use of the foregoing arc plasma gun. The components of the arc plasma gun shown in this figure represented by the same reference numerals used in FIG. 1 are identical to those depicted on FIG. 1 and the detailed explanation of the arc plasma gun will herein be omitted.

According to the present invention, a catalyst layer consisting of catalyst microparticles can be formed using this apparatus. As shown in FIG. 2, this apparatus comprises a cylindrical vacuum chamber 21 and a substrate stage 22 horizontally arranged at the upper portion of the vacuum chamber. A rotating mechanism 23 and a driving means 24 for rotation is provided on the top of the vacuum chamber 21 so that the substrate-supporting stage can be rotated in a horizontal plane.

One or a plurality of substrate 25 to be processed are fixed to and maintained on the face of the substrate stage 22, which is opposed to the bottom of the vacuum chamber 21, while one or a plurality of coaxial arc plasma guns 26 are arranged at the lower portion of the vacuum chamber 21 in such a manner that the opening A of the anode 11 is directed towards the interior of the vacuum chamber. This arc plasma gun is composed of, for instance, a cylindrical anode 11, a rod-like cathode 12 and a ring-like trigger electrode 13. Moreover, the apparatus is so designed that different voltages can be applied to the anode 11, the cathode 12 and the trigger electrode 13.

The DC voltage source 19 as a component of the arc power source 18 has an ability to apply a current of several amperes at a voltage of 800 V therethrough, while the condenser unit 20 is so designed that it can be charged with a DC power source within a predetermined charging time.

The trigger power source 17 is composed of a pulse transformer, it is so designed that a pulse voltage for p seconds corresponding to the input voltage of 200 V is increased to 17 times the initial one and a voltage of 3.4 kV (several A) can thus be outputted therefrom and the trigger power source is connected to the trigger electrode such that the increased voltage can be applied to the trigger electrode 13 with a positive polarity relative to the cathode 12.

To the vacuum chamber 21, there is connected an evacuation system 27 which is composed of, for instance, a turbo pump or a rotary pump and the system permits the evacuation of the chamber even to a vacuum of about 10⁻⁵ Pa. The vacuum chamber 21 and the anode 11 are connected to the ground voltage. In addition, to the vacuum chamber 21, there may be connected a gas-introduction system provided with a gas bomb 28, which serves to introduce an inert gas such as helium gas into the chamber and to micronize ions or the like originated or derived from the catalyst material.

Next, described below in detail is an embodiment of the formation of catalyst microparticles carried out using an apparatus as shown in FIG. 2. First of all, the capacity of a condenser unit 20 is set at a level of 2200 μF, a voltage of 100V is outputted from a DC voltage source 19, the condenser unit 20 is charged at this voltage and the charged voltage is applied to an anode 11 and a cathode 12. In this case, a negative voltage outputted from this condenser unit 20 is applied to a catalyst material 14 through the cathode 12. At this stage, if a pulsed trigger voltage of 3.4 kV outputted from the trigger power source 17 is applied to the cathode 12 and a trigger electrode 13, a trigger discharge (creeping discharge) is induced on the surface of an insulator 15. Moreover, electrons are emitted through the connecting point between the cathode 12 and the insulator 15.

The withstand voltage between the anode 11 and the cathode 12 is reduced due to the foregoing trigger discharge and an arc discharge is generated between the inner peripheral face and the side face of the cathode.

A peak current of not less than 1800 A flows for a time on the order of about 200 μsec due to the discharge of charges accumulated through the charging of the condenser unit 20, the vapor of a catalytic metal is released from the side face of the cathode 12 and it is converted into a plasma. At this time, the arc current generated flows along the Central axis of the cathode 12, while a magnetic field is formed within the anode 11.

The electrons emitted or discharged in the anode 11 fly by the action of the Lorenz force which is generated due to the magnetic field formed by the arc current and which is exerted thereon in the direction opposite to the current flow and the electrons are thus emitted into a vacuum chamber 21 through an opening A.

The vapor of the catalytic metal emitted from the cathode 12 includes ions as the charged particles and neutral particles. In this case, large charged particles whose charge is smaller than the mass of the particle (having a small charge/mass ratio) and neutral particles move straight ahead and come into collision with the wall surface of the anode 11, but ions as charged particles having a large charge/mass ratio fly, while they are attracted by electrons due to the coulomb force and they are then emitted into the vacuum chamber 21 through an opening A.

Substrates to be processed, which are positioned at the upper portion of the chamber at a predetermined distance (for instance, 100 mm) apart from the arc plasma gun 26, pass through the ionic flow, while rotated along concentric circles whose center is in agreement with that of a substrate stage 22 and when the ions included in the vapor of the catalyst metal and discharged in the vacuum chamber 21 arrive at the surface of each substrate, they are adhered to each substrate surface as catalyst microparticles.

An arc discharge is once induced by one time of trigger discharge and an arc current flows for of 300 μsec. If the foregoing condenser unit is charged for about one second, an arc discharge can be generated at a period of 1 Hz. The arc discharge is generated over desired times (for instance, 5 to 1000 times) depending on the desired thickness of the catalyst layer to thus form catalyst microparticles on the surface of the substrate 25 to be processed.

FIG. 2 shows a catalyst microparticle-forming apparatus equipped with a plurality of arc plasma guns, but it is a matter of course that only one arc plasma gun can likewise be used.

Then the CNT growth according to the remote plasma CVD technique will be described below, including the preliminary step for forming micronized catalyst particles.

The remote plasma CVD technique herein used means a method comprising the steps of decomposing a raw gas (reactive gas) into ionic species and/or radical species in a plasma, removing the ionic species formed through the decomposition of the raw gas and present in the decomposed raw gas and growing CNT while making use of the radical species as a starting material.

According to the present invention, the surface of a catalyst layer or that of a substrate provided thereon with a catalyst layer is irradiated with the radical species, which are generated through the decomposition, in a plasma, of a raw gas used for the CNT growth to thus permit the efficient growth of CNT at a low temperature.

The radical species are ones obtained by decomposing, in a plasma, a raw gas such as a hydrogen atom-containing gas (diluted gas) selected from the group consisting of hydrogen gas and ammonia gas and at least one hydrocarbon gas selected from the group consisting of methane, ethane, propane, propylene, acetylene and ethylene, or a carbon atom-containing gas such as a gas of an alcohol selected from methanol and ethanol. For instance, the radical species are hydrogen radicals and carbon radicals which are generated by the decomposition, in a plasma, of a mixed gas comprising a hydrogen atom-containing gas and a carbon atom-containing gas. In this case, the raw gas is decomposed within a plasma generated using, for instance, microwaves or an RF power source, but it is preferred to use microwaves as a means for generating such a plasma since a large amount of radical species can be generated.

When generating radical species according to the foregoing method, ionic species are simultaneously generated and therefore, the latter species should be removed in the present invention. This is because, the drawbacks associated with the ionic species must be eliminated, such that the ionic species have a high kinetic energy and come into collision with the surface of the catalyst layer to thus cause the etching of the same. For instance, the ionic species can be removed by arranging a screening or shielding member as a mesh member having a desired mesh size between the plasma and the catalyst layer or the substrate carrying a catalyst layer formed thereon or by applying a bias voltage of a desired level or a magnetic field. At this stage, the application of a positive voltage ranging from about 10 to 200 V to the mesh member as a bias voltage having a desired level would permit the prevention of any incidence or supply of ionic species upon the substrate surface and the application, to the mesh member, of a magnetic field of not less than about 100 Gauss which is generated by, for instance, passing an electric current through a magnet or a coil, as a magnetic field of a desired level would likewise permit the prevention of any incidence or supply of ionic species upon the substrate surface and the prevention of any etching of the catalyst surface by the impact of the ionic species on the substrate surface. Furthermore, the mesh member to be used is not restricted to one having a specific shape insofar as it can shield and/or prevent any incidence of ionic species upon the substrate surface.

Moreover, the irradiation of the catalyst layer with the radical species may be carried out at the initiation of the increase of the substrate temperature up to the CNT growth, in the middle of the temperature-raising step or after the temperature reaches the growth temperature. The timing of the radical-supply may properly be determined while taking into consideration various factors such as the kind and film thickness of the catalyst metal selected, the conditions of the substrate used, the kind of reactive gas used and the CNT-growing method selected. In the present invention, the substrate is not heated by the radiant heat of the plasma, but is heated and controlled using a separate heating means (such as a lamp heater).

When practicing the foregoing remote plasma CVD technique according to the present invention, preferably used is a substrate provided thereon with a micronized catalyst layer formed using the foregoing arc plasma gun. Usable herein as the targets for the arc plasma gun are, for instance, those composed of at least one member selected from Fe, Co and Ni; or an alloy (alloys such as Fe—Co, Ni—Fe, stainless steel, and inver) or a compound (such as Co—Ti, Fe—Ta, and Co—Mo) containing at least one of these metals; or mixture thereof (such as Fe+TiN, Ni+TiN, and Co+TaN). The use of these catalyst metal-containing targets or those composed of catalyst metals would permit the improvement of the degree of micronization of a catalyst to be formed and likewise simultaneously permit the prevention of the occurrence of any cohesion of catalyst microparticles formed. To further micronize the catalyst and to prevent the occurrence of any cohesion of catalyst microparticles, it is preferred to form, on the substrate, a buffer layer comprising a metal selected from Ti, Ta, Sn, Mo and Al, preferably a nitride selected from TiN, TaN, and AlN, or preferably an oxide selected from Al₂O₃, TiO₂, and Ta₂O₅, as an underlying layer for the catalyst.

Regarding the thickness of the catalyst, when forming an Fe film according to the arc plasma gun technique using an Fe-sintered target, a catalyst layer having a thickness on the order of about 0.1 to 20 nm would sufficiently play the role of a catalyst. Alternatively, when forming an Al film as a buffer layer according to the EB vapor deposition technique, a catalyst layer having a thickness on the order of about 1 to 50 nm would sufficiently play the role of a catalyst, and when forming a TiN film serving as a buffer layer according to the reactive sputtering technique, a catalyst layer having a thickness on the order of about 1 to 50 nm would sufficiently play the role of a catalyst.

In the present invention, the surface of the catalyst layer formed using the plasma gun is preferably activated with hydrogen radicals prior to the growth of CNT. In this respect, it is quite convenient that the activation process for the catalyst surface and the subsequent CNT-growing process are preferably carried out in the same CVD apparatus. More specifically, it is quite favorable to carry out the irradiation with radical species upon the activation of the catalyst surface and the irradiation with radical species upon the CNT-growth in the CVD apparatus used for the growth of CNT. Alternatively, it is also possible to activate the catalyst surface according to the method which comprises the steps of introducing a hydrogen radical-forming gas (such as hydrogen gas) into an apparatus other than the CVD apparatus such as a quartz tube reactor provided with a microwave-generating means, decomposing the gas in a plasma, passing the decomposed gas comprising ionic species and radical species through a mesh member having a desired mesh size to thus remove the ionic species, guiding the hydrogen radical-containing gas into a CVD apparatus, and irradiating, with the radical-containing gas, the surface of a catalyst layer formed on a substrate which is placed in the CVD apparatus to thus activate the surface. The design of the processing methods and/or apparatuses can properly be modified while taking into consideration the purpose of the present invention.

The CNT-growing method according to the present invention can be carried out using any known remote plasma CVD apparatus without any modification or such an apparatus appropriately modified. For instance, the apparatus usable herein can include a CVD apparatus as disclosed in Japanese Un-Examined Patent Publication 2005-350342, which comprises a vacuum chamber, a substrate-supporting stage positioned within the chamber, and a plasma-generating system for generating a desired plasma within the chamber, which is fitted to the side wall of the vacuum chamber According to this CVD apparatus, a CNT-growing gas is introduced into the vacuum chamber and CNT is then formed on the surface of a substrate placed on the substrate-supporting stage according to the vapor phase growth technique. In this case, the substrate-supporting stage is arranged sufficiently distant apart from the plasma-generating region in such a manner that the substrate is not exposed to the plasma generated within the chamber. A means for heating the substrate to a desired temperature is attached to the apparatus.

The remote plasma CVD apparatus usable in the present invention is identical to the aforementioned known remote plasma CVD apparatus provided that a mesh member having a predetermined mesh size is positioned between the plasma-generating region and the substrate to be processed placed on the substrate stage in order to prevent the exposure of the substrate to the plasma generated in the vacuum chamber and to remove the ionic species generated in the plasma. Such a construction would ensure the screening and/or removal of the ionic species generated in the plasma, the irradiation of the substrate surface with the CNT-growing radical species for the growth of CNT having a uniform orientation perpendicular to the substrate surface and the irradiation of the substrate surface with hydrogen radicals prior to the CNT growth for the activation of the surface of the catalyst layer formed on the substrate.

The foregoing plasma CVD apparatus may further be provided with a bias power source so that a bias voltage of a predetermined level can be applied to the substrate instead of the arrangement of a mesh member or in combination with such a mesh member, or the apparatus may further be provided with a means capable of applying, to the substrate, a bias voltage or a magnetic field, of a predetermined level or strength. Such a structure of the plasma CVD apparatus would permit the arrival of the gas decomposed in the plasma at the substrate surface while maintaining its high energy state and the screening and/or removal of the ionic species generated in the plasma. Thus, the substrate surface can be irradiated with a gas containing hydrogen radicals to activate the catalyst surface formed on the substrate and further the substrate thus activated can be irradiated with a gas containing hydrogen radicals and carbon radicals to thus grow CNT having a uniform orientation perpendicular to the substrate surface.

The following is the description of an apparatus as shown in FIG. 3 as an embodiment of the remote plasma CVD apparatus which can be used in the CNT-growing method according to the present invention.

The remote plasma CVD apparatus shown in FIG. 3 is equipped with a vacuum chamber 32 provided with an evacuation means 31 such as a rotary pump or a turbo molecular pump. To the ceiling of the vacuum chamber 32, there is fitted a gas-introduction means 33 such as a shower plate having a known structure. This gas-introduction means 33 is communicated with a gas source (not shown) through a gas-supply tube 34 connected to this gas-introduction means.

Within the vacuum chamber 32 is provided a substrate-supporting stage 35 for placing a substrate S which is opposite to a gas-introduction means 33, and to the side wall of the vacuum chamber 32 is attached, through a waveguide 37, a microwave-generating unit 36 serving as a plasma-generating system for establishing a plasma between the substrate-supporting stage 35 and the gas-introduction means 33. The microwave-generating unit 36 may be one having a known structure, for instance, one having such a structure capable of generating ECR plasma using a slot antenna.

Usable herein as the substrate S which is placed on the substrate-supporting stage 35 and on which CNT is grown through the vapor phase growth technique include, for instance, substrates made of glass, quartz or Si; or substrates consisting of GaN, sapphire or metals such as copper. Among them, in the case of the substrates on which any CNT cannot directly be grown according to the vapor phase growth technique, one which carries a layer of the foregoing catalyst metal/alloy having an arbitrary pattern and formed on any portion on the surface thereof is used. In this case, when forming a layer of the foregoing metal on the surface of a substrate made of, for instance, glass, quartz or Si, a buffer layer as has been described above is formed on the substrate as an underlying layer to prevent any cohesion of catalyst microparticles, to improve the adhesion of the resulting CNT to the substrate and to prevent the formation of any compound between the substrate surface and the catalyst metal.

When practicing the CNT-growing method according to the present invention, the substrate S is first placed on the substrate-supporting stage 35, the interior of the vacuum chamber 32 is evacuated to a desired degree of vacuum by operating the vacuum evacuation means 31, and then the microwave-generating unit 36 is started to thus generate a plasma. Then the substrate S is heated to a predetermined temperature, a gas such as hydrogen gas is introduced into the vacuum chamber 32 to make the same decompose within the plasma. At this stage, ionic species are removed from the decomposed gas through the use of, for instance, the foregoing mesh member, the catalyst surface formed on the substrate S is irradiated with the resulting hydrogen radical-containing gas to thus activate the catalyst metal and subsequently, CNT can be grown on the surface of the substrate S according to the vapor phase growth technique while introducing, into the chamber, the radical species obtained from a raw gas according to the same method to thus grow CNT having uniform orientation perpendicular to the substrate S, on the whole surface of the substrate S or the surface of the patterned portion (catalyst metal pattern formed on the substrate S). In the method described above, the catalyst surface is activated aster the substrate S is heated to a predetermined level, but the activation may likewise be carried out at any time falling within the range of from the initiation of the heating of the substrate to the end of the heating step (at an instance when the temperature reaches the CNT-growing temperature) and therefore, the activation can be carried out simultaneous with the initiation of heating or after the temperature reaches the CNT-growing temperature.

The remote plasma CVD apparatus as shown in FIG. 3 is equipped with a mesh member 38 of a metal material having a desired mesh size and positioned between the plasma-generating region P and the substrate S so as to be opposite to the substrate-supporting stage 35. The attachment of this mesh member would permit the removal of the ionic Species generated through the decomposition of a gas in the plasma and the irradiation of the substrate with the decomposed gas containing only the radical species passing through the mesh member to thus activate the catalyst metal prior to the CNT-growth and to simultaneously prevent the direct exposure of the substrate S to the plasma generated within the vacuum chamber 32 by the operation of the microwave-generating unit 36. In this case, the substrate-supporting stage 35 is arranged within the chamber so as to be distant apart from the plasma-generating region P. In addition, the substrate-supporting stage 35 is also provided with, for instance, a built-in resistance heating type heating means (not shown) for heating the substrate Sup to a predetermined temperature. This heating means permits the control of the temperature of the substrate to a desired level during the step for activating the catalyst and during the step for the vapor phase growth of CNT. In the present invention, the CNT growth is likewise carried out by the irradiation the substrate with the decomposed gas containing radical species obtained by the same method used above.

The foregoing mesh member 38 may be, for instance, one made of stainless steel, and it is arranged within the vacuum chamber 32 in a grounded state or in a floating state. In this case, it would be sufficient that the mesh size of the mesh member 38 ranges from about 1 to 3 mm. If the mesh member 38 has such a mesh size, the mesh member can form an ion sheath region to thus prevent the penetration of plasma particles (ions) into the side of the substrate S and accordingly, the surface of the catalyst metal formed on the substrate can favorably be activated and CNT can likewise favorably be grown. In addition to this, the substrate-supporting stage 35 is arranged so as to be distant apart from the plasma-generating region P and therefore, any direct exposure of the substrate S to the plasma can be prevented. If the mesh size is set at a level of less than 1 mm, however, any gas flow through the same would be interrupted, while if it is set at a Level of greater than 3 mm, the member cannot cut off the plasma and accordingly, even the ionic species can pass through the mesh member 38.

In addition, to favorably activate the catalyst metal and to simultaneously grow CNT having uniform orientation perpendicular to the substrate S, it is needed that the gas decomposed within the plasma should be made arrive at the surface of the substrate S while maintaining its high energy state. To this end, a bias power source 39 for applying a bias voltage to the substrate s may be provided between the mesh member 38 and the substrate S, in addition to the arrangement of the mesh member 38. Thus, only the radical species-containing gas among the gas decomposed within the plasma can pass through the meshes of the mesh member 38 and can smoothly be guided towards the substrate S.

In this case, the bias voltage is set at a level ranging from −400 to 200 V. In this respect, if a voltage of less than −400 V is applied, a discharge is liable to cause, the activation of the catalyst surface accordingly becomes quite difficult and the substrate S and the vapor phase-grown CNT may thus be damaged. On the other hand, if a voltage greater than 200 V is applied, the rate of CNT growth is reduced.

The distance between the mesh member 38 and the substrate S placed on the substrate-supporting stage 35 is preferably set at a level ranging from 20 to 100 mm. This is because, if the distance is shorter than 20 mm, there is observed a tendency of easily causing a discharge between the mesh member 38 and the substrate S. For instance, this is unfavorable for the activation of the catalyst surface and the substrate S and the vapor phase-grown CNT may be damaged. On the other hand, if the distance exceeds 100 mm, the activation of the catalyst and the CNT-growth do not satisfactorily proceed, and the mesh member 38 does not play the role as a counter electrode when applying a bias voltage to the substrate S.

If the distance between the mesh member 38 and the substrate S is thus set as has been described above, the substrate S is not exposed to any plasma even when the plasma is generated after the substrate S is placed on the substrate-supporting stage 35 or the substrate S is not heated by the action of the energy of the plasma and accordingly, the substrate S can be heated only by the built-in heating means of the substrate-supporting stage 35, For this reason, it would be quite easy to control the substrate temperature upon the activation of the catalyst metal surface and the vapor phase-growing of CNT and it would be possible to activate the catalyst metal and to simultaneously form CNT efficiently on the surface of the substrate S according to the vapor phase growth technique at a low temperature and without causing any damage of the substrate.

The foregoing is the detailed description of an embodiment in which the substrate-supporting stage 35 is provided with a built-in heating means, but the present invention is not restricted to this specific embodiment and the heating means is not restricted to any specific one inasmuch as it can raise the temperature of the substrate S placed on the substrate-supporting stage 35 to a desired level.

The foregoing are the descriptions of the processes in which a bias voltage is applied to the substrate S or established between the mesh member 38 and the substrate S in order to make the gas decomposed in the plasma arrive at the substrate S while maintaining its energy, but the present invention is not restricted to these specific embodiment. More specifically, even if any bias voltage is not applied to or established between the mesh member 38 and the substrate S, the catalyst metal can satisfactorily be activated and CNT can efficiently be grown on the surface of the substrate S according to the vapor phase growth technique without causing any damage. In addition, when a dielectric layer such as an SiO₂ layer is formed on the surface of the substrate S, the CNT-growth method can be so designed that a bias voltage ranging from 0 to 200 V can be applied to the substrate S through the bias power source 39 for the purpose of, for instance, preventing any charge up on the surface of the substrate S. In this case, if the bias voltage exceeds 200 V, the catalyst surface cannot efficiently be activated and the rate of CNT growth is reduced.

The present invention will hereunder be described in more specifically with reference to the following Examples.

### Example 1

In this Example, a quartz tube having an inner diameter of 50 mm and provided with a microwave-generator was used, microwaves were introduced into the tube from the exterior in the lateral direction with respect to the tube to thus generate a plasma within the tube and a mixed gas comprising methane gas and hydrogen gas was introduced into the tube as a raw gas to thus decompose the same and to make CNT grow as follows:

First of all, the foregoing mixed gas was introduced, in a ratio by flow rate of methane gas: hydrogen gas=20 sccms 80 sccm, into the quartz tube, which had been evacuated in advance to a vacuum of 2.0 Torr (266 Pa), from one end thereof in the lateral direction and decomposed within a plasma generated by the application of microwaves (under the following operating conditions: a frequency of 2.45 GHz; and an electric power of 500 W). A gas comprising radical species and ionic species obtained through the decomposition of the mixed gas during passing through the plasma was taken out of or blown from the tube through the other end, the ionic species was removed by passing the taken-out gas through a mesh member of stainless steel (mesh size: 1 mm) to thus obtain a radical species-containing gas.

The radical species-containing gas thus prepared was introduced into a known remote plasma CVD apparatus to thus irradiate, with the radical species-containing gas, a substrate, as an objective substrate to be processed, on which a catalyst layer had been formed, for 5 minutes to thus grow CNT. Incidentally, when the foregoing radical species-containing gas is generated using a remote plasma CVD apparatus equipped with a mesh member 38 as shown in FIG. 3, the generation thereof can likewise be carried out within the CVD apparatus.

The foregoing objective substrate used was one prepared by forming, on an Si substrate, a TiN film having a thickness of 40 nm as a buffer layer according to the sputtering technique (under the following process conditions: a target used: Ti target; a sputtering gas used: N₂ gas; a pressure of 0.5 Pa; and an electric power of 300 W) and then forming a catalyst layer on the buffer layer by impacting 100 shots of Ni (film thickness was about 10 Å, since the thickness achieved by a single shot was equal to about 0.1 Å) on the surface thereof according to the arc plasma gun technique (under the following process conditions; a voltage of 60 V; a condenser capacity of 8800 μF; a substrate-target distance of 80 mm). For the purpose of comparison, a separate substrate was provided by forming an Ni film on an Si substrate in a thickness of 1 mm according to the EB (electron beam) technique (under the following process conditions: a pressure of 5×10⁻⁴ Pa; and a film-forming rate of 1 Å/sec) as a catalyst layer.

As a result, the lower limit in the CNT-growing temperature was found to be 400° C. for the substrate whose catalyst layer was formed according to the EB technique, while it could be confirmed that CNT could be grown even at a temperature of 350° C. in the case of the substrate whose catalyst layer was formed according to the arc plasma gun technique.

In addition, it could also be confirmed that CNT could be grown even at a lower temperature on the order of 300° C., when the substrate having the catalyst layer formed according to the arc plasma gun technique was treated with hydrogen radicals at 300° C. under a pressure of 2.0 Torr (266 Pa) before CNT was grown according to the same method used above. FIG. 4 is an SEM image observed for this case.

### Example 2

The same procedures used in Example 1 were repeated except for using a substrate on which the same TiN film as a bluffer layer used in Example 1 was formed in a thickness of 20 nm to thus grow CNT. For the comparative purpose, CNT was likewise grown while using a substrate free of any buffer layer.

As a result, the lower limit in the CNT-growing temperature was found to be 350° C. for the substrate free of any buffer layer, while it could be confirmed that CNT could be grown on the substrate at a temperature of 300° C. in the case of the substrate provided with a buffer layer although the buffer layer was thick on the order of 20 nm.

### Example 3

After a TiN layer as a buffer layer was formed in a thickness of 20 nm according to the procedures used in Example 1 and 100 shots of Ni catalyst were impacted on the buffer layer by the arc plasma gun technique according to the procedures used in Example 1, an Al film serving as a protective layer was formed on the catalyst layer in a thickness of 1 nm (process conditions: a pressure of 5×10⁻⁴ Pa; and a film-forming rate of 1 μ/sec) according to the EB technique. The same procedures used in Example 1 were repeated except for using the substrate thus prepared to grow CNT.

As a result, the growth of CAT could be confirmed even at a temperature of 300° C., it was confirmed that the application of a catalyst-protective layer permitted the improvement of the CNT growth and the acceleration of the CNT-growth as compared with the results observed for the foregoing Examples 1 and 2. FIG. 5 is an SEM image observed for this case.

### Example 4

In this Example, like Example 1, a quartz tube having an inner diameter of 50 mm and provided with a microwave-generator was used, a plasma was generated by the introduction of microwaves from the exterior of the quartz tube in the direction lateral with respect to the tube, then a mixed gas comprising methane gas and hydrogen gas as a raw gas was introduced into the tube to thus decompose the mixed gas and CNT was then grown as follows:

First of all, the foregoing mixed gas was introduced, in a ratio by flow rate of methane gas: hydrogen gas=20 sccm-80 sccm, into the quartz tube, which had been evacuated in advance to a vacuum of 2.0 Torr (266 Pa), from one end thereof in the lateral direction and decomposed within a plasma generated by the application of microwaves (under the following operating conditions; a frequency of 2.45 GHz; and an electric power of 500 W). A gas comprising radical species and ionic species obtained through the decomposition of the mixed gas during passing through the plasma was taken out of or blown from the tube through the other end, the ionic species was removed by passing the taken-out gas through a mesh member of stainless steel (mesh size: 1 mm) to thus obtain a radical species-containing gas.

The radical species-containing gas thus prepared was introduced into a known remote plasma CVD apparatus to thus irradiate, with the radical species-containing gas, a substrate, as an objective subject (550° C.) to be processed, on which a catalyst layer had been formed, for 5 minutes to thus grow CNT. Incidentally, when the foregoing radical species-containing gas is generated using a remote plasma CVD apparatus equipped with a mesh member 38 as shown in FIG. 3, the generation thereof can likewise be carried out within the CVD apparatus.

As the foregoing objective substrate, there were used two kinds of substrates each prepared by forming, on an Si(100) substrate, a TiN film having a thickness of 20 nm as a buffer layer according to the sputtering technique (under the following process conditions: a target used: Ti target; a sputtering gas used: N₂ gas; a pressure of 0.5 Pa; and an electric power of 300 W) and then forming a catalyst layer on the buffer layer by impacting 50 shots or 100 shots of Ni (film thickness was about 5 Å or about 10 Å, respectively, since the thickness thereof achieved by a single shot was equal to about 0.1 Å) on the surface thereof according to the arc plasma gun technique (under the following process conditions: a voltage of 60 V; a condenser capacity of 8800 μF; a substrate-target distance of 80 mm).

FIGS. 6(a) and (b) show the inner diameter distribution observed for CNT grown using the substrate (50 shots) and that observed for CNT grown using the substrate (100 shots), respectively and FIGS. 7(a) and (b) show the outer diameter distribution observed for CNT grown using the substrate (50 shots) and that observed for CNT grown using the substrate (100 shots), respectively. In FIGS. 6 and 7, the diameter (nm) of CNT is plotted as abscissa, while the number of extracted samples is plotted as ordinate. The data plotted on FIGS. 6(a) and (b) clearly indicate that the inner diameter distribution observed for the CNT grown using the substrate (50 shots) differs from that observed for the CNT grown using the substrate (100 shots). In this connection, the inner diameter thereof is very close to the particle size of the catalyst microparticles, Moreover, as will be seen from the data plotted on FIGS. 7(a) and (b), the number of the graphene sheets of CNT ranges from about 2 to 5 and the outer diameter thereof shows a distribution whose center is near about 4 rim, in the case of the CNT grown using the substrate (50 shots), while if the particle size of the catalyst microparticles is large as will be observed in the case of the CNT grown using the substrate (100 shots), the number of the graphene sheets increases, it mainly ranges from 5 to 10 and the center of the distribution thereof resides in about 13 to 15 nm.

### Example 5

In this Example, the same procedures used in Example 4 were repeated except that a catalyst layer was formed by impacting 300 shots (3 nm as expressed in terms of the film thickness) or 100 shots (5 nm as expressed in terms of the film thickness) of Ni as a catalyst to thus grow CNT. As a result, it was found that almost the same CNTs were prepared, and more specifically, in the both cases, the CNTs thus grown was found to have an inner diameter of about 10 nm and an outer diameter of about 20 nm. This is because if the shot number is equal to or higher than 300 (film thickness: 3 nm), the catalyst microparticles would be are stacked.

As has been described above, it would be recognized that the particle size of the catalyst and the inner and outer diameters of the grown CNT can be controlled by adjustment of the shot number of the arc plasma gun upon the formation of a catalyst layer. Therefore, CNT having any desired diameter can be prepared at each operator's own discretion.

In addition, it could also be confirmed, in the same manner as mentioned above, that CNT could be grown, when the substrate prepared according to the arc plasma gun technique was treated with hydrogen radicals at 300° under a pressure of 2.0 Torr (266 Pa) before CNT was grown thereon according to the same method used above.

### INDUSTRIAL APPLICABILITY

The present invention permits the growth of a brush-like CNT at a desired temperature and the easy control of the particle size of the catalyst particles and the inner and/or outer diameters of the resulting grown CNT. Accordingly, the present invention can be applied to the field of semiconductor elements which make use of CNT and other industrial fields.

### BRIEF DESCRIPTION OF THE DRAWINGS

FIG. 1 is a schematic diagram illustrating the outline of a structure of an arc plasma gun used in the present invention.

FIG. 2 is a schematic diagram illustrating the outline of a structure of a catalyst layer-forming apparatus equipped with an arc plasma gun as shown in FIG. 1.

FIG. 3 is a schematic diagram illustrating the outline of a structure of a remote plasma CVD apparatus used for practicing the CNT-growing method according to the present invention.

FIG. 4 is an SEM image observed for the CNT prepared in Example 1.

FIG. 5 is an SEM image observed for the CNT prepared in Example 3.

FIG. 6 shows graphs illustrating the distribution of inner diameters observed for CNTs prepared in Example 4, wherein (a) corresponds to that observed for the shot number of 50, while (b) corresponds to that observed for the shot number of 100.

FIG. 7 shows graphs illustrating the distribution of outer diameters observed for CNTs prepared in Example 4, wherein (a) corresponds to that observed for the shot number of 50, while (b) corresponds to that observed for the shot number of 100.

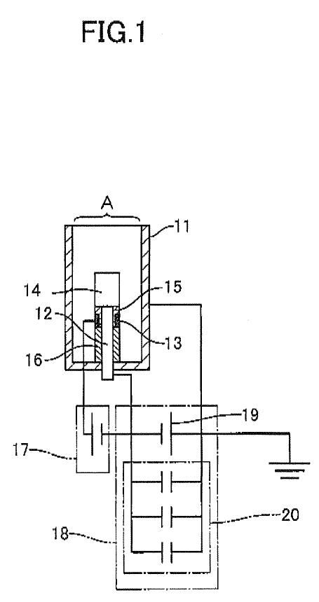

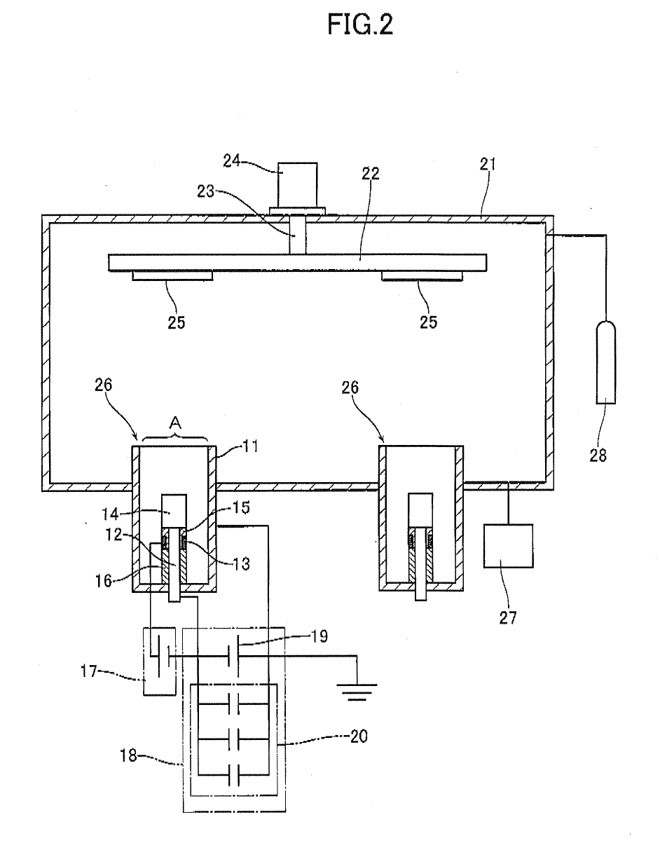

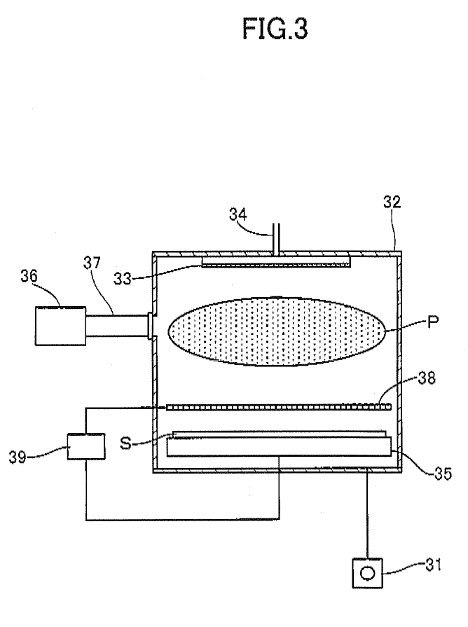

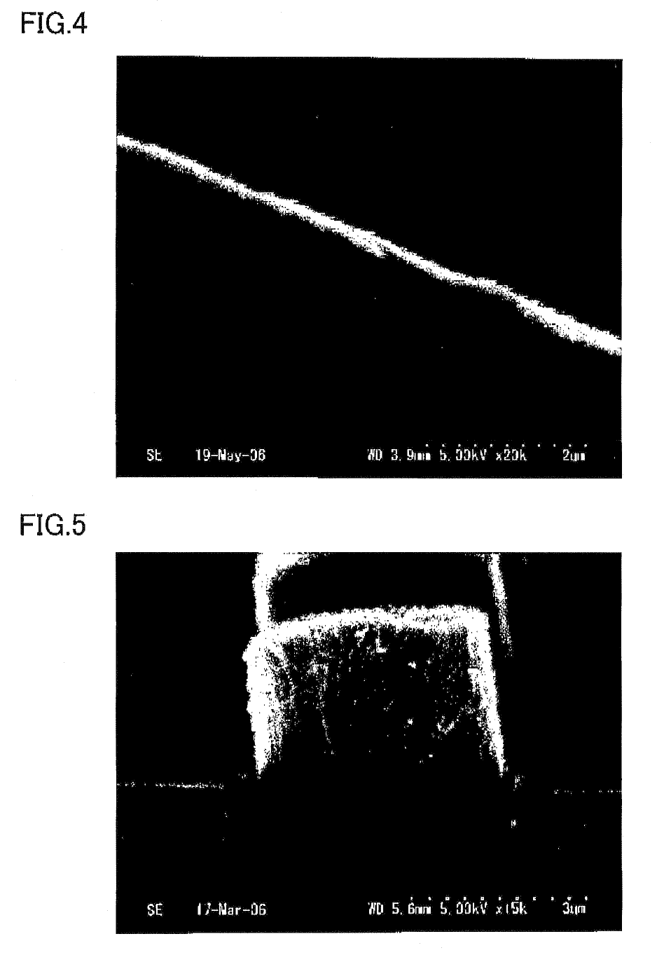

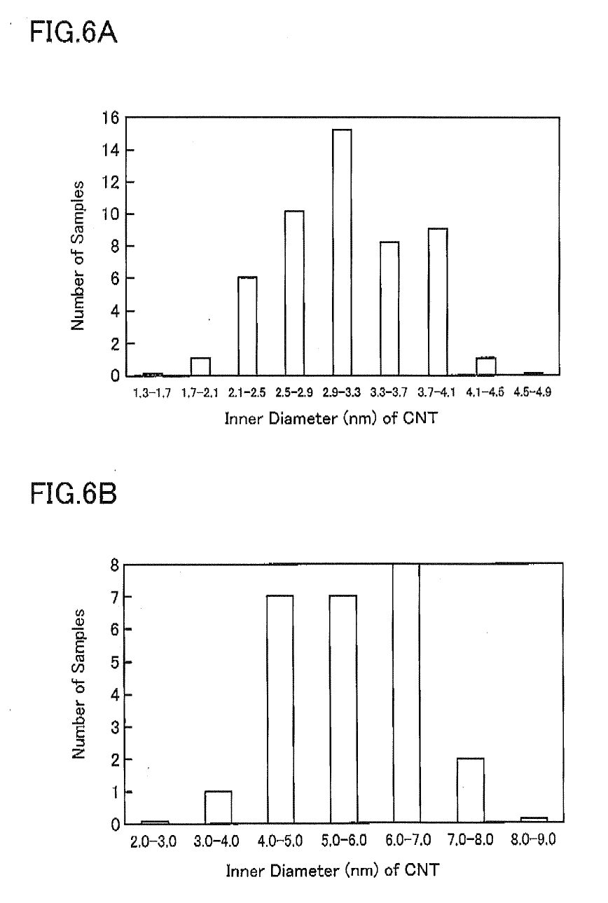

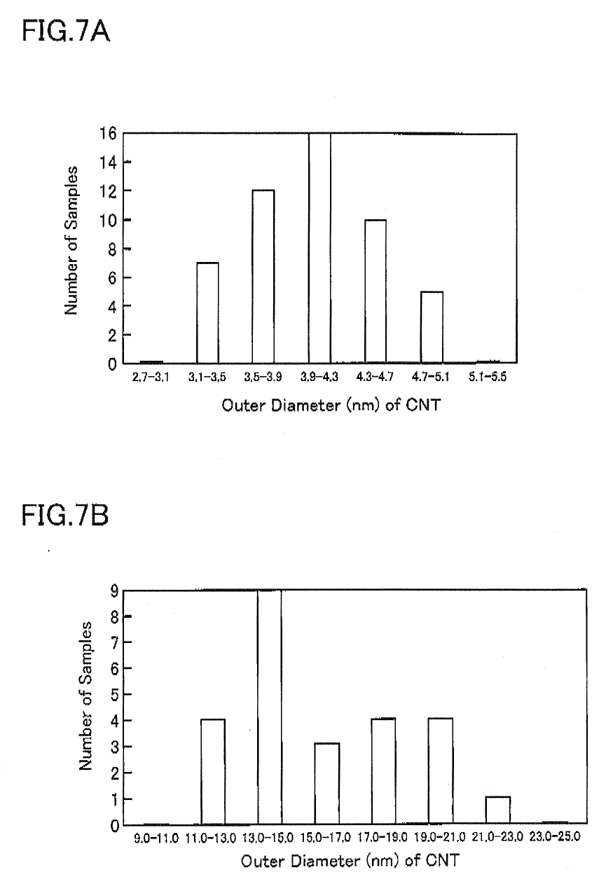

### EXPLANATION OF SYMBOLS USED

11 . . . anode;
12 . . . cathode;
13 . . . trigger electrode;
14 . . . catalyst material;
15 . . . insulator;
16 . . . dielectric material;
17 . . . trigger power source;
18 . . . arc power source;
19 . . . DC voltage source;
20 . . . condenser unit;
21 . . . vacuum chamber;
22 . . . substrate-supporting stage;
23 . . . rotating mechanism;
24 . . . driving means for rotation;
25 . . . substrate to be processed;
26 . . . arc plasma gun;
27 . . . vacuum evacuation system;
28 . . . gas-introduction system;
31 . . . evacuation means;
32 . . . vacuum chamber;
33 . . . gas-introduction means;
34 . . . gas-supply pipe;
35 . . . substrate-supporting stage;
36 . . . microwave-generating unit (generator);
37 . . . waveguide;
38 . . . mesh member;
39 . . . bias power source;
S . . . substrate;
P . . . plasma-generating region.

1. A substrate for growing a carbon nanotube characterized in that the substrate has, on a surface, a catalyst layer formed through the use of an arc plasma gun.

2. The substrate for growing a carbon nanotube as set forth in claim 1, wherein the catalyst layer consists of catalyst microparticles whose particle size is controlled in proportion to the shot number of the arc plasma gun.

3. The substrate for growing a carbon nanotube as set forth in claim 1, wherein the substrate is further provided with a buffer layer as an underlying layer for the catalyst layer.

4. The substrate for growing a carbon nanotube as set forth in claim 3, wherein the buffer layer is a film of a metal selected from the group consisting of Ti, Ta, Sn, Mo and Al, a film of a nitride of such a metal, or a film of an oxide of such a metal.

5. The substrate for growing a carbon nanotube as set forth in claim 1, wherein the catalyst layer is one formed using, as a target for the arc plasma gun, a metal selected from the group consisting of Ve, Co and Ni; or an alloy or a compound containing at least one of these metals; or
a mixture of at least two members selected from the group consisting of these metals, the alloys and the compounds.

6. The substrate for growing a carbon nanotube as set forth in claim 1, wherein the catalyst layer is further subjected to an activation treatment with hydrogen radicals after the formation thereof.

7. The substrate for growing a carbon nanotube as set forth in claim 1, wherein the catalyst layer is provided with, on the surface thereof, a catalyst-protective layer consisting of a metal or a nitride.

8. The substrate for growing a carbon nanotube as set forth in claim 7, wherein the metal used as a material for the catalyst-protective layer is one selected from the group consisting of Ti, Ta, Sn, Mo and Al, and the nitride is a nitride of such a metal.

9. A method for growing carbon nanotubes comprising the steps of forming a catalyst layer on a surface of a substrate using an arc plasma gun; and growing carbon nanotubes on the catalyst layer by a thermal CVD technique or a remote plasma CVD technique.

10. The method for growing carbon nanotubes as set forth in claim 9, wherein the substrate is one provided with a buffer layer as an underlying layer for the catalyst layer.

11. The method for growing carbon nanotubes as set forth in claim 10, wherein the buffer layer is a film of a metal selected from the group consisting of Ti, Ta, Sn, Mo and Al, a film of a nitride of such a metal, or a film of an oxide of such a metal.

12. The method for growing carbon nanotubes as set forth claim 9, wherein a target for the arc plasma gun is one consisting of a metal selected from the group consisting of Fe, Co, and Ni; or an alloy or a compound containing at least one of these metals; or a mixture of at least two members selected from the group consisting of these metals, the alloys and the compounds.

13. The method for growing carbon nanotubes as set forth in claim 9, wherein after the formation of the catalyst layer, it is activated with hydrogen radicals and then the carbon nanotubes are grown on the activated catalyst layer.

14. The method for growing carbon nanotubes as set forth claim 9, wherein after the formation of the catalyst layer, a catalyst-protective layer consisting of a metal or a nitride is formed on the catalyst layer.

15. The method for growing carbon nanotubes as set forth in claim 14, wherein the metal used as a material for the catalyst-protective layer is one selected, from the group consisting of Ti, Ta, Sn, Mo and Al, and the nitride is a nitride of such a metal.

16. A method for controlling a particle size of catalyst microparticles characterized in that when forming a catalyst layer on the surface of a substrate using an arc plasma gun, the particle size of catalyst microparticles is controlled by changing the number of shots of the arc plasma gun.

17. The method for controlling a particle size of catalyst microparticles as set forth in claim 16, wherein the substrate used is provided with a buffer layer.

18. The method for controlling a particle size of catalyst microparticles as set forth in claim 17, wherein the buffer layer is a film of a metal selected from the group consisting of Ti, Ta, Sn, Mo and Al, a film of a nitride of such a metal, or a film of an oxide of such a metal.

19. The method for controlling a particle size of catalyst microparticles as set forth in claim 16, wherein a target for the arc plasma gun is one consisting of a metal selected from the group consisting of Fe, Co and Ni; or an alloy or a compound containing at least one of these metals; or a mixture of at least two members selected from the group consisting of these metals, the alloys and the compounds.

20. A method for controlling a diameter of a carbon nanotube comprising the steps of forming a catalyst layer on a, surface of a substrate using an arc plasma gun, while controlling a catalyst particle size according to the method as set forth in claim 16, and then growing carbon nanotubes on the size-controlled catalyst layer according to a thermal CVD technique or a remote plasma CVT) technique to thus control the diameter of the grown carbon nanotubes.

21. The method for controlling a diameter of a carbon nanotube as set forth in claim 20, wherein after forming the catalyst layer, the catalyst is activated with hydrogen radicals and then the carbon nanotube is grown on the catalyst layer.

22. The method for controlling a diameter of a carbon nanotube as set forth in claim 20, wherein after forming the catalyst layer, a catalyst-protecting layer consisting of a metal or a nitride is farmed on a surface of the catalyst layer.

23. The method, for controlling a diameter of a carbon nanotube as set forth in claim 22, wherein the metal used for farming the catalyst-protecting layer is one selected from the groups consisting of Ti, Ta, Sn, Mo and Al and the nitride is a nitride of such a metal.
